(19) United States
(12) Patent Application Publication
(10) Pub. No.: US 2023/0156405 A1
(43) Pub. Date: May 18, 2023

(54) MICROSPEAKER HAVING A FLEXIBLE PRINTED CIRCUIT BOARD AS A DIAPHRAGM

(71) Applicant: EM-TECH Co., Ltd., Gyeongsangnam-do (KR)

(72) Inventors: Byung Min Yu, Seoul (KR); Jae Hwa Lim, Gyeongsangnam-do (KR); Young Uk Jo, Gyeongsangnam-do (KR); Yong Hee Oh, Gyeongsangnam-do (KR); Yong Dae So, Gyeongsangnam-do (KR)

(21) Appl. No.: 17/986,480

(22) Filed: Nov. 14, 2022

(30) Foreign Application Priority Data
Nov. 16, 2021 (KR) 10-2021-0157525

(51) Int. Cl. H04R 9/02; H05K 1/16; H05K 1/02

(52) U.S. Cl. CPC H04R 9/025; H05K 1/16; H05K 1/028

(57) ABSTRACT

A microspeaker in which a diaphragm and a voice coil are replaced with a flexible printed circuit board (FPCB) is provided. The microspeaker includes: a magnetic circuit having a yoke and a magnet; and an FPCB diaphragm installed on the magnetic circuit and having a conductive coil pattern formed on a non-conductive film. When an electric signal is applied to the conductive coil pattern of the FPCB diaphragm, the FPCB diaphragm vibrates by mutual electromagnetic force with the magnetic circuit to generate sound.

### TECHNICAL FIELD

The present disclosure relates to a microspeaker using a flexible printed circuit board (FPCB) as a diaphragm.

### BACKGROUND

With the development of true wireless stereo (TWS) technology for the convenience of users, a more compact structure has been required for earphones. In addition, as audio equipment has been spread, the level of sound quality desired by users has increased, and accordingly, higher performance and high-quality sound characteristics are required for audio equipment.

In general, microspeakers employing a dynamic structure adopt a voice coil that generates mutual electromagnetic force with a magnetic circuit to convert an electrical signal into a physical motion and include a diaphragm to which a voice coil is attached to convert the physical motion into sound. A vibration plate is provided. However, since a relatively heavy voice coil is attached to a thin and light diaphragm, a weight of a vibration system increases and a response speed decreases, which deteriorates the performance during high-pitched sound reproduction.

Therefore, it is required to develop a microspeaker capable of reducing the weight of the vibration system and improving the performance of sound reproduction.

### SUMMARY

An aspect of the present disclosure is to provide a microspeaker in which a diaphragm and a voice coil are replaced with a flexible printed circuit board (FPCB).

In an aspect of the present disclosure, a microspeaker using a flexible printed circuit board (FPCB) as a diaphragm includes a magnetic circuit having a yoke and a magnet and an FPCB diaphragm installed on the magnetic circuit and having a conductive coil pattern formed on a non-conductive film, wherein when an electric signal is applied to the conductive coil pattern of the FPCB diaphragm, the FPCB diaphragm vibrates by mutual electromagnetic force with a magnetic circuit to generate sound.

In another example of the present disclosure, the microspeaker may further includes: a damper installed between FPCB diaphragm and the magnetic circuit.

In another example of the present disclosure, the conductive coil pattern may be formed on both upper and lower surfaces of the non-conductive film.

In another example of the present disclosure, the non-conductive film may be formed of a polymer compound such as polyamide, a PET film, an elastomer, and silicone rubber.

In another example of the present disclosure, the conductive coil pattern may be formed of a highly conductive material such as Cu, Al, Au, or Ag.

Unlike the dynamic speaker structure of the related art, the microspeaker provided in the present disclosure uses an FPCB as a diaphragm, thereby improving high-pitched sound reproduction performance and having a reduced size.

In addition, in the microspeaker provided in the present disclosure, since the FPCB vibrates directly to generate sound, sound distortion may be reduced and clear sound may be reproduced, compared to the existing structure in which a voice coil is attached to a diaphragm to transmit vibration.

### BRIEF DESCRIPTION OF THE DRAWINGS

FIG. 1 is a perspective view of a microspeaker using a flexible printed circuit board (FPCB) as a diaphragm according to a first embodiment of the present disclosure.

FIG. 2 is a cross-sectional view taken along line A-A of FIG. 1.

FIG. 3 is a cross-sectional view of a microspeaker using an FPCB as a diaphragm according to a second embodiment of the present disclosure.

FIG. 4 is a cross-sectional view of a microspeaker using an FPCB as a diaphragm according to a third embodiment of the present disclosure.

### DETAILED DESCRIPTION

Hereinafter, the present disclosure will be described in more detail with reference to the accompanying drawings.

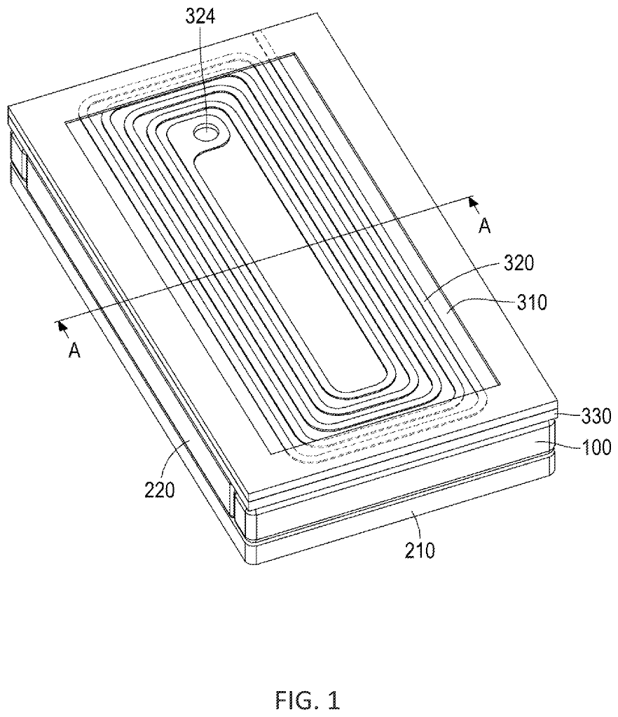

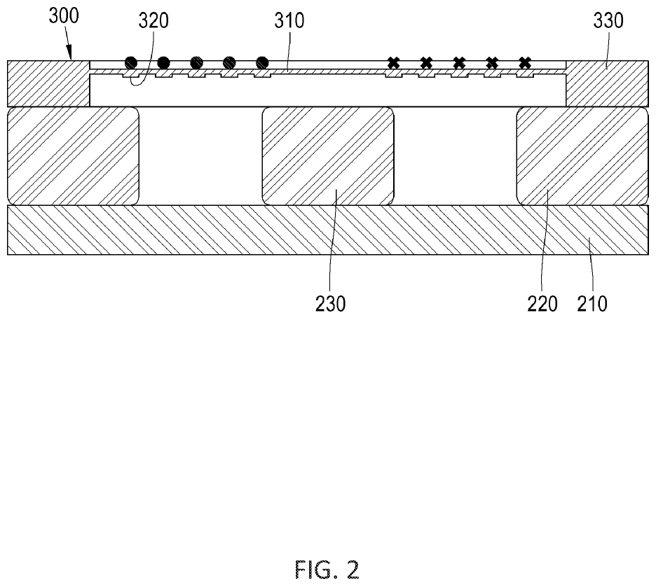

FIG. 1 is a perspective view of a microspeaker using an FPCB as a diaphragm according to a first embodiment of the present disclosure, and FIG. 2 is a cross-sectional view taken along line A-A of FIG. 1.

A microspeaker using an FPCB as a diaphragm according to the first embodiment of the present disclosure is formed to have a rectangular shape as a whole, and accordingly, a yoke 210 or an FPCB diaphragm 300 is also formed to have a rectangular shape.

Two or more rod-shaped magnets 210 and 220 are disposed parallel to a longer side of the yoke 210 at a distance from each other on the rectangular yoke 210. In the first embodiment of the present disclosure, a side magnet 220 disposed along the edge of the longer side of the yoke 210 and a center magnet 230 disposed in the center between the side magnet 220 are included. A frame 100 is disposed on a shorter side of the yoke 210 to support the FPCB diaphragm 300.

In the FPCB diaphragm 300, a conductive coil pattern 320 formed of a highly conductive material, such as Cu, Al, Au, or Ag is formed on a non-conductive film 310 formed of a polymer compound, such as polyamide, PET film, elastomer, or silicone rubber, and a terminal 330 for transmitting an electrical signal to the conductive coil pattern 320 is provided.

The conductive coil pattern 320 is preferably disposed in a gap between the magnets 210 and 220 as shown in FIGS. 1 and 2. When the conductive coil pattern 320 is concentrated in the gap portion between the magnets 210 and 220, a magnetic field may be concentrated and induced in the gap between the magnets 210 and 220 on the FPCB diaphragm 300, and accordingly, an amplitude of the FPCB diaphragm 300 may increase, thereby improving the performance of the microspeaker using the FPCB as a diaphragm.

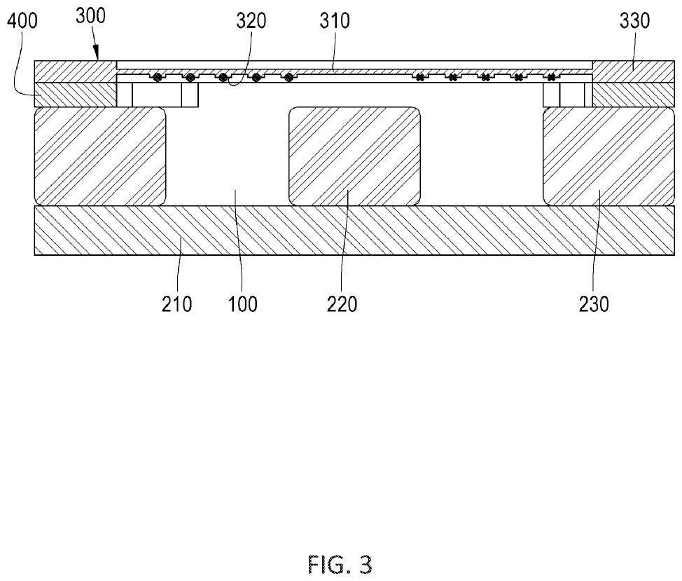

FIG. 3 is a cross-sectional view of a microspeaker using an FPCB as a diaphragm according to a second embodiment of the present disclosure.

The microspeaker using an FPCB as a diaphragm according to the second embodiment of the present disclosure has all the same components as those of the first embodiment, except that a damper 400 is installed on the frame 100 and the side magnet 220 to support the diaphragm 300.

Since the damper 400 is installed, a distance between the diaphragm 300 and the magnets 210 and 220 may be constantly maintained.

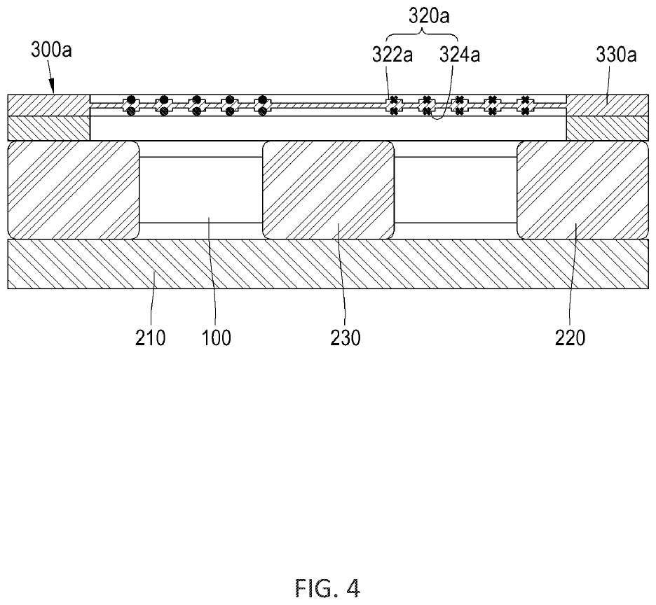

FIG. 4 is a cross-sectional view of a microspeaker using an FPCB as a diaphragm according to a third embodiment of the present disclosure. The microspeaker using an FPCB as a diaphragm according to the third embodiment of the present disclosure is different from the first embodiment in that a conductive coil pattern 320a is formed on both upper and lower surfaces of a diaphragm 300a.

An upper conductive coil pattern 322a formed on an upper surface of a non-conductive film 310a and a lower conductive coil pattern 324a formed on a lower surface of the non-conductive film 310a need to match in the direction of an induced magnetic force to improve vibration performance by the mutual electromagnetic force with the magnets 220 and 230, and therefore, winding directions thereof match each other.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A microspeaker, comprising:
a magnetic circuit having a yoke and a magnet; and
a flexible printed circuit board (FPCB) diaphragm installed on the magnetic circuit and having a conductive coil pattern formed on a non-conductive film,
wherein when an electric signal is applied to the conductive coil pattern of the FPCB diaphragm, the FPCB diaphragm vibrates by mutual electromagnetic force with the magnetic circuit to generate sound.

2. The microspeaker of claim 1, further comprising a damper installed between the FPCB diaphragm and the magnetic circuit.

3. The microspeaker of claim 1, wherein the conductive coil pattern is formed on both upper and lower surfaces of the non-conductive film.

4. The microspeaker of claim 1, wherein the non-conductive film is formed of a polymer compound.

5. The microspeaker of claim 4, wherein the polymer compound is selected from the group consisting of: polyamide, a PET film, an elastomer, and silicone rubber.

6. The microspeaker of claim 1, wherein the conductive coil pattern is formed of a highly conductive material.

7. The microspeaker of claim 6, wherein the highly conductive material is selected from the group consisting of: Cu, Al, Au, and Ag.

8. The microspeaker of claim 1, wherein two or more magnets are disposed to be spaced apart from each other, and the conductive coil pattern is disposed in a gap between the two or more magnets.
